(19) United States
(12) Patent Application Publication
(10) Pub. No.: US 2008/0180174 A1
(43) Pub. Date: Jul. 31, 2008

(54) Output buffer with a controlled slew rate offset and source driver including the same

(76) Inventors: Hyung-tae KIM, Hwaseong-si (KR); Chang-sig KANG, Suwon-si (KR); Chon-wook PARK, Seoul (KR)

Correspondence Address: LEE & MORSE, P.C., 3141 FAIRVIEW PARK DRIVE, SUITE 500, FALLS CHURCH, VA, 22042, US

(21) Appl. No.: 12/000,155

(22) Filed: Dec. 10, 2007

(30) Foreign Application Priority Data
Jan. 27, 2007 (KR) 10-2007-0008655

(51) Int. Cl. H03F 3/45

(52) U.S. Cl. 330/253; 345/204

(57) ABSTRACT

Example embodiments relate to an output buffer having a differential input circuit configured to convert a differential voltage signal input through a positive input terminal and a negative input terminal into a differential current signal, and configured to output the differential current signal. The differential input circuit may include a plurality of PMOS transistors and a plurality of NMOS transistors. The output buffer may further include a slew rate matching circuit configured to compensate for a difference between components of a first parasitic capacitor formed around the plurality of PMOS transistors and components of a second parasitic capacitor formed around the plurality of NMOS transistors.

### BACKGROUND OF THE INVENTION

1. Field of the Invention

Example embodiments relate to a display device and, more particularly, to a source driver including an output buffer.

2. Description of the Related Art

Liquid crystal display devices (LCDs) are becoming widely used in devices, e.g., laptop computers and TVs, due to its small and low power consumption characteristics. In particular, active matrix type LCDs using a thin film transistor (TFT) as a switching device, which may display images, e.g., moving images, are becoming widely used.

Conventional LCDs may include a liquid crystal panel, a source driver, a gate driver, a timing controller, a power generator and a DC/DC converter. The liquid crystal panel may include pixels arranged in a matrix. The source driver may drive source lines (SLs) of the liquid crystal panel. The gate driver may drive gate lines (GLs) of the liquid crystal panel. The timing controller may control the source driver and the gate driver. The power generator may generate driving voltages to drive the source driver, the gate driver and the timing controller. The DC/DC converter may generate a common voltage (Vcom) used in the liquid crystal panel.

Pixels forming the liquid crystal panel may be disposed at a position where the GLs and the SLs cross at right angles. A gate electrode of a TFT may be connected to the GL, a source electrode may be connected to the SL, and a drain electrode may be connected to a pixel electrode of a liquid crystal capacitor. The liquid crystal capacitor may be connected between the pixel electrode and a common electrode. In addition, the drain electrode may be connected to a storage capacitor Cst used to reduce leakage current of the liquid crystal capacitor. The Vcom generated by the DC/DC converter may be applied to the common electrode.

The conventional source driver that drives the SLs may include a digital-to-analog converter, output buffers, output switches and charge sharing switches. In addition, the SLs may have loads consisting of a resistor and a parasitic capacitor.

The digital-to-analog converter may convert input digital image signals D_DAT into analog image signals A1, A2, . . . , and An to be output. The analog image signals A1, A2, . . . , and An may indicate gray level voltage.

The output buffers may amplify the corresponding analog image signals A1, A2, . . . , and An and may output the signals to the corresponding output switches. The output switches may respond to a pair of first control signals SW and /SW and output amplified analog image signals B1, B2, . . . , and Bn to the SLs.

The output buffers may increase the driving ability of analog voltage input from the digital-to-analog converter and deliver signals sharing an increased driving ability to the SLs. The output buffers may provide output signals having an identical charging property and matching property to the entire panel.

The conventional output buffer, which may be embodied by a rail-to-rail operational amplifier, may have a structure in which PMOS transistors and NMOS transistors may be symmetrically arranged with respect to each other. Therefore, parasitic capacitors respectively formed in an upper part and a lower part of the output buffer may be asymmetric with respect to each other. Asymmetry of the parasitic capacitors may cause a difference in small signal gain characteristic and, thus, a change in slew rate may be provided.

More specifically, due to the parasitic capacitor formed in the upper part of the output buffer in the PMOS transistors, which may be relatively larger than the parasitic capacitor formed in the lower part of the output buffer in the NMOS transistors, the time required in a pull-up operation may be increased, e.g., the time required in a pull-up operation may be longer as compared to the time required in a pull-down operation. This produces a slew rate offset in the parasitic capacitors.

### SUMMARY OF THE INVENTION

Example embodiments are therefore directed to an output buffer, which may substantially overcome one or more of the problems due to the limitations and disadvantages of the related art.

It is therefore a feature of example embodiments to provide an output buffer to improve quality of a displayed image.

It is therefore another feature of example embodiments to provide an output buffer to reduce a slew offset of an output signal output from the output buffer.

It is therefore another feature of example embodiments to provide a source driver having the output buffer.

At least one of the above and other features of example embodiments may be to provide to an output buffer having a differential input circuit configured to convert a differential voltage signal input through a positive input terminal and a negative input terminal into a differential current signal so as to output the differential current signal. The differential input circuit may include a plurality of PMOS transistors and a plurality of NMOS transistors. The output buffer may further include a slew rate matching circuit configured to compensate for a difference between components of a first parasitic capacitor formed around the plurality of PMOS transistors and components of a second parasitic capacitor formed around the plurality of NMOS transistors.

The output buffer may further include a current summing circuit configured to sum up the differential current signal output from the differential input circuit and a floating current signal output from a floating current source, and an output circuit configured to respond to the bias current output from the current summing circuit and configured to amplify the differential voltage signal to output the amplified differential voltage signal. The current summing circuit may be configured to generate a predetermined bias current.

The slew rate matching circuit may include a compensation capacitor having a capacitance corresponding to the difference between the components of the first parasitic capacitor and the components of the second parasitic capacitor. The capacitor may be at least one of a passive element and an active element. The slew rate matching circuit may include a compensation capacitor having a capacitance corresponding to the difference between a width of a gate of the PMOS transistor and a width of a gate of the NMOS transistor. The slew rate matching circuit may be connected between the differential input circuit and a ground voltage.

The differential input circuit may include a first differential amplifier connected to the ground voltage through a first transistor and a second differential amplifier connected to the ground voltage through a second transistor. The slew rate matching circuit may be connected between the first differential amplifier and the ground voltage and may be connected to the first transistor in parallel. The first differential amplifier may include two differential transistors whose sources may be connected to each other, and the slew rate matching circuit may be connected between a source terminal of the differential transistors and a source terminal of the first transistor.

The output buffer may further include a current summing circuit configured to sum up a differential current signal output from the differential input circuit and a floating current signal output from a floating current source included in the output buffer to output the summed signal. The current summing circuit may include a first current mirror circuit and a second current mirror circuit. The first current mirror circuit may be connected between a power voltage and the floating current source, and the second current mirror circuit may be connected between the ground voltage and the floating current source. The first current mirror circuit may receive a first differential current signal output from the first differential amplifier and the second current mirror circuit may receive a second differential current signal output from the second differential amplifier.

The output buffer may further include an output circuit configured to respond to a predetermined bias current and configured to amplify a differential voltage signal input to a differential input circuit of the output buffer, so as to output the amplified differential voltage signal. The slew rate matching circuit may be connected between the output circuit and a ground voltage. The output circuit may further include a first transistor and a second transistor, and the slew rate matching circuit may be connected between the second transistor and the ground voltage. The sources of the first and second transistors may be connected to power voltage, drains of the first and second transistors may be connected to each other, and gates of the first and second transistors respectively may receive bias current. The slew rate matching circuit may be connected between the gate of the second transistor and the ground voltage. The first current mirror circuit may be configured to output a first bias current to a gate of the first transistor included in the output circuit and the second current mirror circuit may be configured to output a second bias current to a gate of the second transistor included in the output circuit. The slew rate matching circuit may be connected to the second current mirror circuit and the ground voltage.

Another feature of example embodiments may relate to an output buffer including a folded cascode amplifier having a plurality of PMOS transistors and a plurality of NMOS transistors symmetrically arranged with respect to each other. The output buffer may include a slew rate matching circuit configured to compensate for a difference between components of a first parasitic capacitor formed around the plurality of PMOS transistors and components of a second parasitic capacitor formed around the plurality of NMOS transistors.

Another feature of example embodiments may relate to a source driver which may output a source line driving signal for driving a source line in a panel. The source driver may include a digital-to-analog converter configured to convert a digital image signal input from a timing controller into an analog image signal and configured to output the analog image signal, and an output buffer configured to stably amplify the analog image signal output from the digital-to-analog converter and configured to output the amplified analog image signal. The output buffer may include a slew rate matching circuit having a folded cascode amplifier where a plurality of PMOS transistors and a plurality of NMOS transistors may be symmetrically arranged with respect to each other and configured to compensate for a difference between components of a first parasitic capacitor formed around the plurality of PMOS transistors and components of a second parasitic capacitor formed around the plurality of NMOS transistors.

### BRIEF DESCRIPTION OF THE DRAWINGS

The above and other features and advantages of the example embodiments will become more apparent to those of ordinary skill in the art by describing in detail example embodiments thereof with reference to the attached drawings, in which:

FIG. 1 illustrates a diagram of an output buffer according to an example embodiment;

FIG. 2 illustrates a diagram of an output buffer according to another example embodiment;

FIG. 3 illustrates a waveform diagram of a source line driving signal for comparing effects of an example embodiment and a conventional art;

FIG. 4 illustrates a table for comparing effects of an example embodiment and a conventional art;

FIG. 5 illustrates a block diagram of a liquid crystal display device; and

FIG. 6 illustrates a block diagram of a source driver illustrated in FIG. 5.

### DETAILED DESCRIPTION OF THE INVENTION

Korean Patent Application No. 10-2007-0008655, filed on Jan. 27, 2007, in the Korean Intellectual Property Office, and entitled: “Output Buffer for Matching Up Slew Rate with Down Slew Rate and Source Driver Including the Same,” is incorporated by reference herein in its entirety.

Example embodiments will now be described more fully hereinafter with reference to the accompanying drawings. The invention may, however, be embodied in different forms and should not be construed as limited to the embodiments set forth herein. Rather, these example embodiments are provided so that this disclosure will be thorough and complete, and will fully convey the scope of the invention to those skilled in the art.

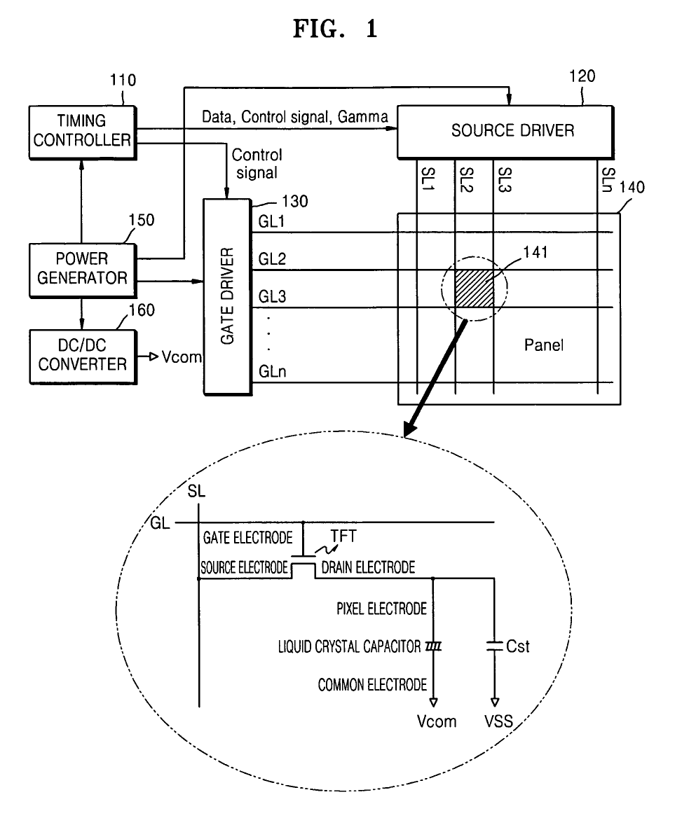

Referring to FIG. 1, an output buffer 100 may include a differential input circuit 110, a current summing circuit 120, a floating current source 130, an output circuit 140 and a slew rate matching circuit 150.

The differential input circuit 110 may include first differential transistors 112 and second differential transistors 114. The first differential transistors 112 may include transistors MN1 and MN2, and the second differential transistors 114 may include transistors MP1 and MP2. The first differential transistors 112 may be connected to a ground voltage through a transistor MN3, and the second differential transistors 114 may be connected to a power voltage through a transistor MP3.

The first differential transistor 112 may be formed of NMOS transistors MN1 and MN2 and may amplify a voltage difference between input signals INP and INN to output a first differential current signal. The second differential transistor 114 may be formed of PMOS transistors MP1 and MP2 and may amplify a voltage difference between input signals INP and INN to output a second differential current signal.

The current summing circuit 120 may be formed of a first current mirror circuit 122 and a second current mirror circuit 124. The current summing circuit 120 may sum up a differential current signal output from the differential input circuit 110 and a floating current signal output from the floating current source 130, and may provide the summed signal as a bias signal (a pull-up signal or pull-down signal) to the output circuit 140.

The first current mirror circuit 122 may be connected between the power voltage and the floating current source 130, and may receive the first differential current signal from the first differential transistor 112. The second current mirror circuit 124 may be connected between the ground voltage and the floating current source 130, and may receive the second differential current signal from the second differential transistor 114.

The first current mirror circuit 122 may include a plurality of PMOS transistors MP4, MP5, MP6 and MP7, which may have a negative feedback configuration. The second current mirror circuit 124 may include a plurality of NMOS transistors MN4, MN5, MN6, and MN7.

A gate of the PMOS transistor MP5 and a gate of the PMOS transistor MP7 may be commonly connected to a drain of the NMOS transistor MN5. The PMOS transistors MP7 and MP5 may be respectively connected to the NMOS transistors MN1 and MN2, which may form the first differential transistor 112. A second bias voltage VB2 may be applied to gates of PMOS transistors MP4 and MP6.

A gate of the NMOS transistor MN5 and a gate of the NMOS transistor MN7 may be commonly connected to a drain of the NMOS transistor MN4. The NMOS transistors MN7 and MN5 may be respectively connected to the PMOS transistors MP1 and MP2, which may form the second differential transistor 114. A fifth bias voltage VB5 may be applied to gates of the NMOS transistors MN4 and MN6.

The floating current source 130 may be connected between the first current mirror circuit 122 and the second current mirror circuit 124. The floating current source 130 may provide a first floating current signal to the first current mirror circuit 122 and a second floating current signal to the second current mirror circuit 124. The floating current source 130 may include a plurality of PMOS transistors MP8 and MP9 and NMOS transistors MN8 and MN9.

The PMOS transistor MP8 and the NMOS transistor MN8 may be connected in series between a fifth node N5 and a seventh node N7. The PMOS transistor MP9 and the NMOS transistor MN9 may be connected in series between a sixth node N6 and an eighth node N8. A third bias voltage VB3 may be applied to gates of the PMOS transistors MP8 and MP9, and a fourth bias voltage VB4 may be applied to gates of the NMOS transistors MN8 and MN9.

The output circuit 140 may include a PMOS transistor MP10 for pulling up an output signal OUT and an NMOS transistor MN10 for pulling down the output signal OUT. In addition, the output circuit 140 may further include two capacitors C1 and C2 to stabilize a frequency characteristic of the output signal OUT and prevent the output signal OUT from oscillating.

A first voltage VDD, e.g., a power voltage, may be applied to a source of the PMOS transistor MP10 and a pull-up signal may be applied to a gate of the PMOS transistor MP10 to drive the PMOS transistor MP10. A second voltage VSS, e.g., a ground voltage, may be applied to a source of the NMOS transistor MN10 and a pull-down signal may be applied to a gate of the NMOS transistor MN10 to drive the NMOS transistor MN10. The pull-up signal and the pull-down signal may be bias signals.

The slew rate matching circuit 150 may include a compensation capacitor C3, which may be at least one of a passive element and an active element. The active element may include one transistor. The slew rate matching circuit 150 may compensate for a difference between components of the parasitic capacitor formed around the PMOS transistors and components of the parasitic capacitor formed around the NMOS transistors.

The slew rate matching circuit 150 may be connected between the sources of the NMOS transistors MN1 and MN2, which may include the first differential transistor 112 and the second voltage VSS. The source of the NMOS transistor MN3 may be connected to the second voltage VSS, and thus, the slew rate matching circuit 150 may be directly connected to the source of the NMOS transistor MN3.

The capacitance of the compensation capacitor C3 may correspond to a difference between components of the parasitic capacitor formed around the PMOS transistors MP1 through MP10 and components of the parasitic capacitor formed around the NMOS transistors MN1 through MN10. For example, when the sum total of the components of the parasitic capacitor of the NMOS transistors is approximately 300 pF and the sum total of the components of the parasitic capacitor of the PMOS transistors is approximately 900 pF, the capacitance of the compensation capacitor C3 may be approximately 600 pF.

In addition, the capacitance of the compensation capacitor C3 may correspond to a difference between the width of the gates of the PMOS transistors MP1 through MP10 and the width of the gates of the NMOS transistors MN1 through MN10. For example, when a semiconductor device is silicon (Si) or gallium-arsenic (GaAs), an electron mobility may be approximately three times or approximately ten times larger than a hole mobility. Further, during the manufacturing of the transistors, the width of the gate of PMOS transistor may be increased so as to determine the capacitance corresponding to the difference between a width of the gate of the PMOS transistor and the NMOS transistor.

In an example embodiment, one end part of the slew rate matching circuit 150 may be connected to the common source of the NMOS transistors MN1 and MN2, and the other end part thereof may be connected to the second voltage VSS. Therefore, current output from the NMOS transistors MN1 and MN2 may flow into the slew rate matching circuit 150, which may include the compensation capacitor C3. As a result, pull-up speed may be increased and pull-down speed may be decreased so as to match the slew rate.

The operation of the output buffer 100 will now be described herein as follows.

(1) When the first voltage signal INP is larger than the second voltage signal INN (e.g., when a voltage signal having a relatively high level is applied to the gate of the NMOS transistor MN1), current flowing through the NMOS transistor MN1 may be increased, and thus, the voltage of the fourth node N4 may be decreased. Further, when the second bias voltage VB2 is applied to the gate of the PMOS transistor MP6, the voltage of the sixth node N6 may also be decreased.

Further, a voltage signal having a low level may be applied to the PMOS transistor MP10, and thus, current flowing through the PMOS transistor MP10 may be increased. As a result, the output voltage OUT may be increased, e.g., according to the first voltage signal INP input into a positive input terminal.

Further, because the compensation capacitor C3 having uniform capacitance may be connected to the common source of the NMOS transistors MN1 and MN2, voltage of the fourth node N4 may be increased more rapidly to electrically charge the compensation capacitor C3. Accordingly, the voltage of the sixth node N6 may be rapidly decreased, and the turn-on speed of the PMOS transistor MP10 may also be increased. Therefore, the output voltage OUT may increase more rapidly.

(2) When the first voltage signal INP is smaller than the second voltage signal INN (e.g., when a voltage signal having a relatively low level is applied to the gate of the NMOS transistor MN1), current flowing through the NMOS transistor MN2 may be increased, and thus, the voltage of the third node N3 may be decreased. Further, when the second bias voltage VB2 is applied to the gate of the PMOS transistor MP4, the voltage of the fifth node N5 may also be decreased. Accordingly, a voltage signal having a low level may be applied to the PMOS transistor MP7, and thus, current flowing through the PMOS transistor MP7 may be increased.

Accordingly, voltages of the fourth node N4 and sixth node N6 may be increased. The voltage having a high level may be applied to the gate of the PMOS transistor MP10, and thus, current flowing in the PMOS transistor MP10 may be decreased. As a result, the output voltage OUT may be decreased e.g., the output voltage OUT may be decreased according to the first voltage signal INP input into a positive input terminal.

Further, when the first current mirror circuit 122 is formed of a negative feedback configuration (when the voltage of the third node N3 is decreased), the voltage of the fifth node N5 may also be decreased. Accordingly, current flowing through the PMOS transistor MP5 may be increased, and thus, voltage of the third node N3 may be increased. That is, due to a feedback configuration (when voltage of a node is increased), the voltage of the node may be decreased after a predetermined time.

Because the compensation capacitor C3 having uniform capacitance may be connected to the common source of the NMOS transistors MN1 and MN2, the voltage of the third node N3 may be decreased more rapidly to electrically charge the compensation capacitor C3. Contrarily, in a negative feedback configuration, current flowing in the PMOS transistor MP5 may be increased, and thus, the voltage of the third node N3 may be increased again.

Further, the compensation capacitor C3 may reduce a voltage rising speed of the third node N3. Accordingly, due to the reduced voltage rising speed of the third node N3, a voltage rising speed of the fourth node N4 may be reduced. Further, the second bias voltage VB2 with uniform amplitude may be applied to the gate of the PMOS transistor MP6, so that a reduction in voltage rising speed of the sixth node N6 may be achieved. Further, turn-off speed of the PMOS transistor MP10 may be decreased, so as to reduce the falling speed of output voltage OUT.

As a result, because the slew rate matching circuit 150 including the capacitor C3 may be connected to common sources of the NMOS transistors MN1 and MN2, the slew rate may be increased or decreased, during the respective up-slewing operation or down-slewing operation. Therefore, the skew rate matching circuit 150 may match the up slew rate with the down slew rate.

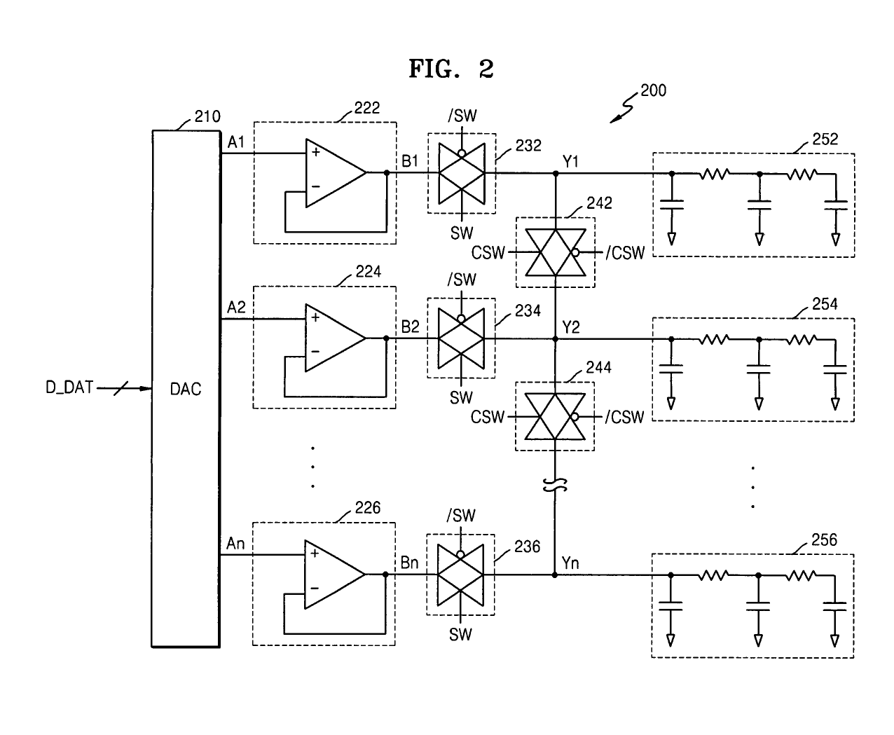

Referring to FIG. 2, an output buffer 200 may include a differential input circuit 210, a current summing circuit 220, a floating current source 230, an output circuit 240 and a slew rate matching circuit 250. The output buffer 200 may include the same elements as in the output buffer 100, illustrated in FIG. 1 other than the arrangement of the slew rate matching circuit 250. Therefore, a detailed description of the same elements mentioned in FIG. 1 will not be discussed herein for brevity sake.

The slew rate matching circuit 250 may be connected between the output circuit 240 and the second voltage VSS. In addition, the slew rate matching circuit 250 may be connected between a second mirror circuit 224 and the second voltage VSS. More particularly, the slew rate matching circuit 250 may be connected between an output terminal of the second mirror circuit 224 and an input terminal of the output circuit 240. The slew rate matching circuit 250 may compensate for a difference between components of a first parasitic capacitor formed around the PMOS transistors and components of a second parasitic capacitor formed around the NMOS transistors. The slew rate matching circuit 250 may include a compensation capacitor C4, which may be formed of a passive element or an active element.

Further, the operations and/or functions of the first slew rate matching circuit 150 (as shown in FIG. 1) and the second slew rate matching circuit 250 (as shown in FIG. 2) may be different. In particular, the first slew rate matching circuit 150 may be used to prevent and/or reduce a slew rate offset in an output signal when the output buffer 100 receives an input signal to generate an output signal, and the second slew rate matching circuit 250 may be used to prevent and/or reduce a slew rate offset in a source line driving signal when the second slew rate matching circuit 250 generates a source line driving signal from the output signal.

Further, all SLs may be pre-charged with a common voltage when a charge sharing operation is initiated. Further, the output signal of the output buffer 200 may be input in each of the SLs when the charge sharing operation is completed. Accordingly, the output voltage may be affected by a voltage that may be pre-charged in the source line, and due to such coupling, the level of the output voltage may be temporarily changed. In particular, the voltage change according to the coupling may be transmitted to fourth and tenth nodes N4 and N10 by capacitors C1 and C2, so as to reduce and/or prevent oscillation in the output circuit 240 (and reflected in the output voltage).

Further, components of the first parasitic capacitor formed around the PMOS transistors and components of the second parasitic capacitor formed around the NMOS transistors may be different. Therefore, the coupling may affect the output voltage differently, e.g., due to asymmetrically formed parasitic capacitors, the coupling may affect the pull-up bias signal and the pull-down bias signal in a different manner.

Further, when the slew rate matching circuit 250 including the capacitor C4 is connected between the output terminal of the second current mirror circuit 224 and the output terminal of the output circuit 240, the capacitor C4 may be driven by the second current mirror circuit 224 with a small signal resistance to perform a buffering function while generating the pull-down bias current. This may delay the falling time of the output voltage, so that the up slew rate and the down slew rate match.

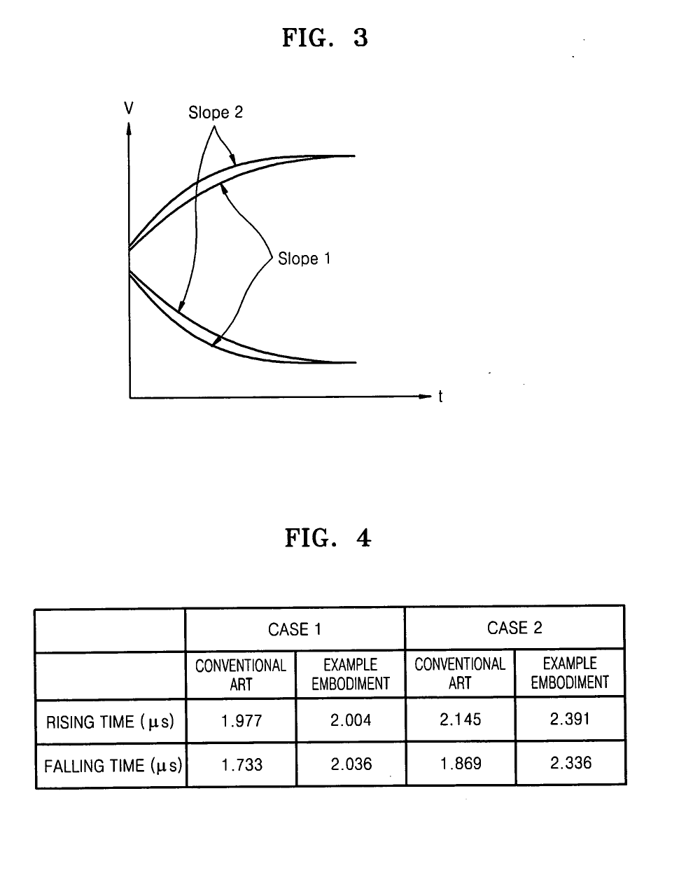

FIG. 3 illustrates a waveform diagram of a source line driving signal for comparing effects of example embodiments and conventional art; and FIG. 4 illustrates a table for comparing effects of example embodiments and conventional art.

Referring to FIG. 3, slope 1 may indicate a source line driving signal output from an output buffer according to the conventional art, and slope 2 may indicate a source line driving signal output from an output buffer according to the example embodiment. Slope 2 may have a lower down slew rate and a higher up slew rate than that of slope 1.

Referring to FIG. 4, the rising and falling times of the source line driving signal is illustrated. In the table, Case 1 and Case 2 illustrate that the rising time may be slightly increased as compared to the falling time, e.g. a small offset may be found in the rising time as compared to the falling time. For example, in Case 1, the offset rising time may be approximately 0.027 μs, and in Case 2, the offset rising time may be approximately 0.246 μs. The rising time and the falling time indicate the time required to reach approximately 90% of a target voltage and approximately 10% of a target voltage, respectively.

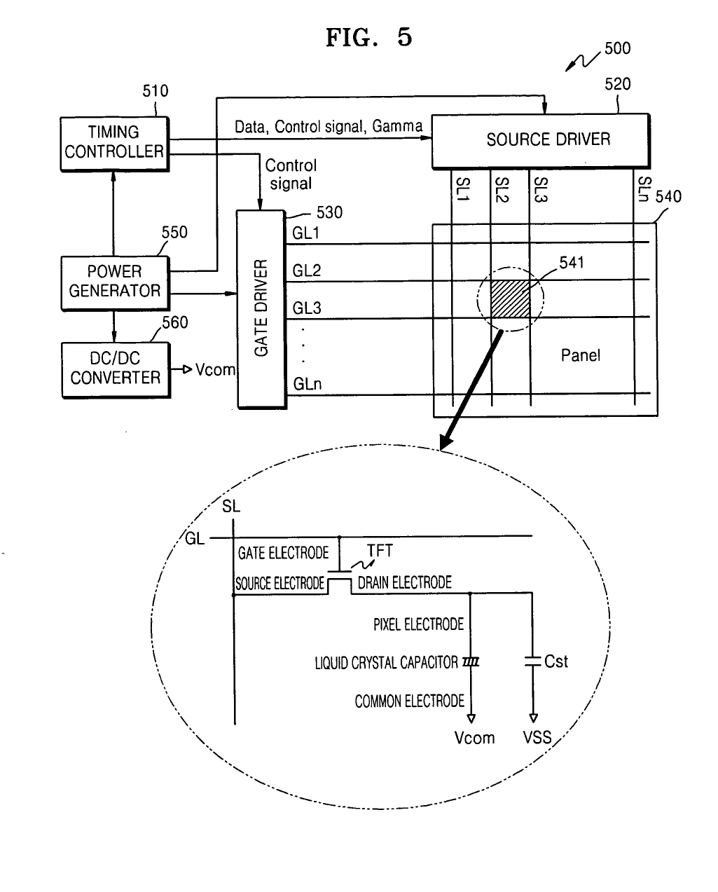

Referring to FIG. 5, a LCD 500 may include a liquid crystal panel 540, a source driver 520, a gate driver 530, a timing controller 510, a power generator 550 and a DC/DC converter 560. The liquid crystal panel 540 may include pixels 541 arranged in a matrix. The source driver 520 may drive SLs of the liquid crystal panel 540. The gate driver 530 may drive GLs of the liquid crystal panel 540. The timing controller 510 may control the source driver 520 and the gate driver 530. The power generator 550 may generate driving voltages to drive the source driver 520, the gate driver 530 and the timing controller 510. The DC/DC converter 560 may generate a Vcom used in the liquid crystal panel 540. The Vcom may be approximately ½ the level of the power voltage.

Pixels 541 forming the liquid crystal panel 540 may be disposed at a position where the GLs and the SLs cross at right angles. A gate electrode of a TFT may be connected to a GL, a source electrode may be connected to a SL, and a drain electrode may be connected to a pixel electrode of a liquid crystal capacitor. The liquid crystal capacitor may be connected between the pixel electrode and a common electrode. In addition, the drain electrode may be connected to a storage capacitor Cst used to reduce leakage current of the liquid crystal capacitor. The Vcom generated by the DC/DC converter 560 may be applied to the common electrode.

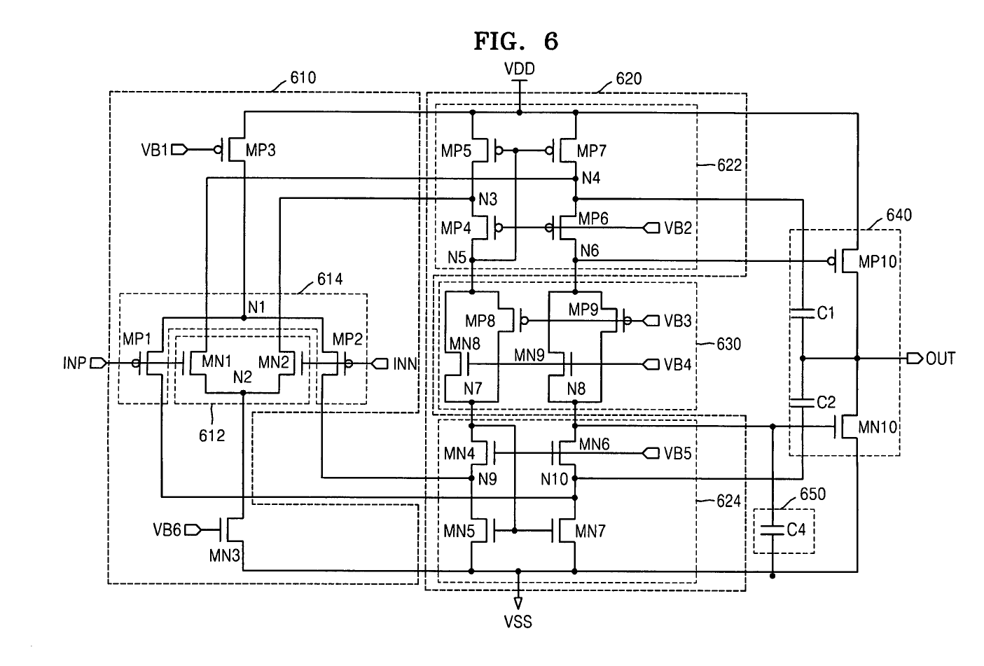

Referring to FIG. 6, a source driver 600 may include a digital-to-analog converter 610, output buffers 622, 624 and 626, output switches 632, 634 and 636 and charge sharing switches 642 and 644. In addition, the SLs may have loads 652, 654 and 656 having a resistor and a parasitic capacitor.

The digital-to-analog converter 610 may convert input digital image signals D_DAT into analog image signals A1, A2, . . . , and An to be output. The analog image signals A1, A2, . . . , and An may indicate gray level voltage.

The output buffers 622, 624 and 626 may amplify the corresponding analog image signals A1, A2, . . . , and An and may output the signals to the corresponding output switches 632, 634 and 636. The output switches 632, 634 and 636 may respond to a pair of first control signals SW and /SW and may output amplified analog image signals B1, B2, . . . , and Bn to the SLs.

The output buffers 622, 624 and 626 may increase the driving ability of analog voltage input from the digital-to-analog converter 210 and may deliver signals shaving an increased driving ability to the SLs. The output buffers 622, 624 and 626 may provide output signals having an identical charging property and matching property to the entire panel. The output buffers 622, 624 and 626 may be configured in accordance with either example embodiments.

The charge sharing switches 642 and 644 may respond to a pair of second control signals CSW and /CSW, and may control the voltage level of the driving signals of the SLs to be the common voltage level at a predetermined time. This may be referred to as pre-charging operation. A pair of the second control signals CSW and /CSW may have opposite levels to a pair of the first control signals SW and /SW.

As discussed above, the time required in a conventional pull-up operation is increased because the parasitic capacitor formed in the upper part of output buffers including PMOS transistors is relatively larger than the parasitic capacitor formed in the lower part output buffers including the NMOS transistors, e.g., the time required in a pull-up operation may be longer than the time required in a pull-down operation. This may create an offset (or non-matching rate) during the up slew rate and the down slew rate.

Example embodiments may provide matching rising and falling times of an output signal output from an output buffer, so as to improve quality of displayed images.

Example embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the example embodiments as set forth in the following claims.

What is claimed:

1. An output buffer, comprising:
a differential input circuit configured to convert a differential voltage signal input through a positive input terminal and a negative input terminal into a differential current signal and configured to output the differential current signal, the differential input circuit including a plurality of PMOS transistors and a plurality of NMOS transistors; and
a slew rate matching circuit configured to compensate for a difference between components of a first parasitic capacitor formed around the plurality of PMOS transistors and components of a second parasitic capacitor formed around the plurality of NMOS transistors.

2. The output buffer as claimed in claim 1, further comprising:
a current summing circuit configured to sum up the differential current signal output from the differential input circuit and a floating current signal output from a floating current source, the current summing circuit configured to generate a predetermined bias current; and
an output circuit configured to respond to the bias current output from the current summing circuit and configured to amplify the differential voltage signal to output the amplified differential voltage signal.

3. The output buffer as claimed in claim 1, wherein the slew rate matching circuit further comprising a compensation capacitor having a capacitance corresponding to the difference between the components of the first parasitic capacitor and the components of the second parasitic capacitor.

4. The output buffer as claimed in claim 3, wherein the capacitor is at least one of a passive element and an active element.

5. The output buffer as claimed in claim 1, wherein the slew rate matching circuit further comprising a compensation capacitor having a capacitance corresponding to the difference between a width of a gate of the PMOS transistor and a width of a gate of the NMOS transistor.

6. The output buffer as claimed in claim 1, wherein the slew rate matching circuit is connected between the differential input circuit and a ground voltage.

7. The output buffer as claimed in claim 6, wherein the differential input circuit comprises a first differential amplifier connected to the ground voltage through a first transistor and a second differential amplifier connected to the ground voltage through a second transistor, and
the slew rate matching circuit being connected between the first differential amplifier and the ground voltage, and the slew rat matching circuit being connected to the first transistor in parallel.

8. The output buffer as claimed in claim 7, wherein the first differential amplifier comprises two differential transistors whose sources are connected to each other, and
the slew rate matching circuit being connected between a source terminal of the differential transistors and a source terminal of the first transistor.

9. The output buffer as claimed in claim 6, further comprising a current summing circuit configured to sum up a differential current signal output from the differential input circuit and a floating current signal output from a floating current source included in the output buffer to output the summed signal,
wherein the current summing circuit is formed of a first current mirror circuit and a second current mirror circuit, the first current mirror circuit being connected between a power voltage and the floating current source and the second current mirror circuit being connected between the ground voltage and the floating current source.

10. The output buffer as claimed in claim 9, wherein the first current mirror circuit is configured to receive a first differential current signal output from the first differential amplifier and the second current mirror circuit is configured to receive a second differential current signal output from the second differential amplifier.

11. The output buffer as claimed in claim 1, further comprising an output circuit configured to respond to a predetermined bias current and configured to amplify a differential voltage signal input to a differential input circuit of the output buffer, so as to output the amplified differential voltage signal, and
the slew rate matching circuit being connected between the output circuit and a ground voltage.

12. The output buffer as claimed in claim 1 1, wherein the output circuit comprises a first transistor and a second transistor, and
the slew rate matching circuit being connected between the second transistor and the ground voltage.

13. The output buffer as claimed in claim 12, wherein sources of the first and second transistors are connected to a power voltage, drains of the first and second transistors are connected to each other, and gates of the first and second transistors respectively receive bias current, and
the slew rate matching circuit being connected between the gate of the second transistor and the ground voltage.

14. The output buffer as claimed in claim 11, further comprising a current summing circuit configured to sum up a differential current signal output from the differential input circuit and a floating current signal output from a floating current source included in the output buffer, to output the summed signal,
wherein the current summing circuit is formed of a first current mirror circuit and a second current mirror circuit, the first current mirror circuit being connected between a power voltage and the floating current source, and the second current mirror circuit being connected between a ground voltage and the floating current source.

15. The output buffer as claimed in claim 14, wherein the first current mirror circuit is configured to output a first bias current to a gate of the first transistor included in the output circuit and the second current mirror circuit is configured to output a second bias current to a gate of the second transistor included in the output circuit.

16. The output buffer as claimed in claim 15, wherein the slew rate matching circuit is connected to the second current mirror circuit and the ground voltage.

17. An output buffer including a folded cascode amplifier having a plurality of PMOS transistors and a plurality of NMOS transistors symmetrically arranged with respect to each other, the output buffer comprising:
a slew rate matching circuit configured to compensate for a difference between components of a first parasitic capacitor formed around the plurality of PMOS transistors and components of a second parasitic capacitor formed around the plurality of NMOS transistors.

18. The output buffer as claimed in claim 17, wherein the slew rate matching circuit further comprising a compensation capacitor having a capacitance corresponding to the difference between components of the first parasitic capacitor and components of the second parasitic capacitor.

19. A source driver which outputs a source line driving signal for driving a source line in a panel, the source driver comprising:
a digital-to-analog converter configured to convert a digital image signal input from a timing controller into an analog image signal and configured to output the analog image signal; and
an output buffer configured to stably amplify the analog image signal output from the digital-to-analog converter and configured to output the amplified analog image signal,
wherein the output buffer includes a slew rate matching circuit having a folded cascode amplifier so that a plurality of PMOS transistors and a plurality of NMOS transistors are symmetrically arranged with respect to each other, the slew rate matching circuit being configured to compensate for a difference between components of a first parasitic capacitor formed around the plurality of PMOS transistors and components of a second parasitic capacitor formed around the plurality of NMOS transistors.

20. The source driver as claimed in claim 19, wherein the slew rate matching circuit further comprising a compensation capacitor having a capacitance corresponding to the difference between the components of the first parasitic capacitor and the components of the second parasitic capacitor.
